(19) United States
(12) Patent Application Publication
(10) Pub. No.: US 2010/0017686 A1
(43) Pub. Date: Jan. 21, 2010

(54) FAST CHANNEL ZAPPING AND HIGH QUALITY STREAMING PROTECTION OVER A BROADCAST CHANNEL

(76) Inventors: Michael Luby, Berkeley, CA (US); Thomas Stockhammer, Bergen (DE); Mohammad Amin Shokrollahi, Preverenges (CH)

Correspondence Address: QUALCOMM INCORPORATED, 5775 MOREHOUSE DR., SAN DIEGO, CA, 92121, US

(21) Appl. No.: 12/437,251

(22) Filed: May 7, 2009

Related U.S. Application Data
(60) Provisional application No. 61/051,325, filed on May 7, 2008.

(51) Int. Cl. G06F 15/16; H03M 13/05; G06F 11/10

(52) U.S. Cl. 714/776; 709/231; 714/E11.032

(57) ABSTRACT

Signaling the sending of source blocks within multiple physical layer blocks is done for both streaming and object delivery applications, using minimal additional overhead, and in some cases no overhead, to signal interleaved source blocks within a physical layer block, signaling how symbols are related to the source blocks from which they are generated, and signaled sending and indications of prioritized data for source blocks. Organizing and sending streams over one more channels can be done to improve the quality of delivered streams, while minimizing or improving the needed amount of channel resources and receiver power resources needed.

This applications claims the benefit of U.S. Provisional Application No. 61/051,325 entitled “Fast Channel Zapping and High Quality Streaming Protection over a Broadcast Channel” filed on May 7, 2008.

### FIELD OF THE INVENTION

The present invention relates to streaming and object delivery in general and in particular to streaming and object delivery over less reliable channels using FEC to protect the quality of the delivered stream.

### BACKGROUND OF THE INVENTION

It has become common practice to consider sending streaming data, typically audio and/or video data but also other types of data such a telemetric data, over a channel. One primary concern is to ensure that the quality of the delivered stream is high, for example that all or most of the original stream data is delivered to a receiver or set of receivers, or that the video quality of the play-out at a receiver or a set of receivers is high. For example, the channel over which the streaming data is delivered may be not completely reliable, e.g., parts of the data are lost or corrupted in transmission. Thus often it is the case that other measures need to be taken to overcome delivery degradation in order to achieve a high quality delivery, wherein such measures may include the application of FEC to the original data stream, for example at the physical layer to protect against packet corruption or at the link, transport or application layer to protect against packet loss. Other measures include using a retransmission strategy to retransmit lost or corrupted data, for example a link layer retransmission protocol or an application layer retransmission protocol.

Another primary concern when designing such a system is for example the amount of time it takes to start showing a video stream from the time an end user first requests to start viewing the video stream, or the amount of time it takes to stop showing a current video stream and start showing a new video stream triggered by a user request. This amount of time is often referred to as the channel zapping time. Typically, the smaller the channel zapping time the better the end user experience and thus the more valuable the overall service. For example, it is often a requirement that the channel zapping time be as small as possible, e.g., under 1 second.

It is often possible to achieve such channel zapping times and high quality stream delivery when the streams are delivered over highly reliable channels with no backchannel, or when the streams are delivered over less reliable channels and when there is a backchannel that can be used to request retransmission of lost data, but it is often a challenge to achieve such channel zapping times when the stream are delivered over less reliable channels and when a back channel is not to be used to enhance reliability, and instead the use of FEC might be appropriate.

Recently, it has become common practice to consider using FEC codes for protection of streaming media during transmission. When sent over a packet network, examples of which include the Internet and wireless networks such as those standardized by groups such as 3GPP, 3GPP2 and DVB, the source stream is placed into packets as it is generated or made available, and thus the packets are used to carry the source stream in the order it is generated or made available to receivers. In a typical application of FEC codes to these types of scenarios, the FEC code is used to add additional repair packets to the original source packets containing the source stream, and these repair packets have the property that when source packet loss occurs received repair packets can be used to recover the data contained in the lost source packets. In other examples, it is possible that partial packet loss occurs, i.e., receivers may lose parts of a packet while receiving other parts of that packet, and thus in these examples wholly or partially received repair packets can be used to recover wholly or partially lost source packets. In yet other examples, other types of corruption can occur to the sent data, e.g., values of bits may be flipped, and thus repair packets may be used to correct such corruption and provide as accurate as possible recovery of the source packets. In other examples, the source stream is not necessarily sent in discrete packets, but instead may be sent for example as a continuous bit-stream.

There are many examples of FEC codes that can be used to provide protection of a source stream. Reed-Solomon codes are well known codes for error and erasure correction in communication systems. For erasure correction over, for example, packet data networks, a well-known efficient implementation of Reed-Solomon codes is to use Cauchy or Vandermonde matrices as described in L. Rizzo, “Effective Erasure Codes for Reliable Computer Communication Protocols”, Computer Communication Review, 27(2):24-36 (April 1997) (hereinafter “Rizzo”) and J. Bloemer, M. Kalfane, R. Karp, M. Karpinski, M. Luby, D. Zuckerman, “An XOR-Based Erasure-Resilient Coding Scheme”, Technical Report TR-95-48, International Computer Science Institute, Berkeley, Calif., (1995) (hereinafter “XOR-Reed-Solomon”). Other examples of FEC codes include LDPC codes, chain reaction codes and multi-stage chain reaction codes, such as those described in U.S. Pat. No. 6,307,487 (hereinafter “Luby I”) and U.S. Published Patent App. No. 2003/0058958 (hereinafter “Shokrollahi I”), respectively, which are incorporated herein for all purposes.

Examples of the FEC decoding process for variants of Reed-Solomon codes are described in “Rizzo” and “XOR-Reed-Solomon”. In these examples, decoding is applied once sufficient source and repair data packets have been received. The decoding process may be computationally intensive and, depending on the CPU resources available, this may take considerable time to complete, relative to the length of time spanned by the media in the block. In many applications, packets are further sub-divided into symbols on which the FEC process is applied. A symbol can have any size, but often the size of a symbol is at most equal to the size of the packet. Hereinafter, we call the symbols comprising the encoding block the “source symbols,” and the symbols generated during the FEC process the “encoding symbols.” For some FEC codes, notably Reed-Solomon codes, the encoding and decoding time grows impractical as the number of encoding symbols per source block grows. Thus, in practice, there is often an upper bound, e.g., 255, on the total number of encoding symbols that can be generated per source block. Since symbols are often placed into different packet payloads this sometimes places a practical upper bound on the maximum length on the encoding of a source block, e.g., if a packet payload is at most 1024 bytes then an encoded source block can be at most 255 KB (kilobytes), and this is also of course an upper bound on the size of the source block itself if each symbol is sent in a separate packet.

It is often desirable to apply the FEC encoding and decoding on blocks of data within a stream that is sent spread out over a large period of time, since applying FEC coding over blocks of data that is sent over a larger interval of time generally provides better protection to the stream for the same bandwidth overhead as FEC coding over blocks of data that is sent over a smaller interval of time. This is because many channels are subject to time correlated loss and/or corruption characteristics, e.g., data is likely to be lost in bursts, or there is likely to be short periods of time when the channel characteristics are much worse than they are over other short intervals of time.

A challenge with using FEC encoding applied to blocks of data that is sent spread out over a larger interval of time is that this can adversely affect the channel zapping time. For example, at the receiver a block of encoded data may only be able to be fully recovered and played out after enough data for the entire block has been received. Thus, if the block of FEC encoded data is sent over a larger interval of time then the channel zapping time may be unacceptably high.

One method for achieving the objective of short channel zapping time while at the same time sending a block of FEC encoded data over a larger interval of time is to order the data in such a way that the most important data is sent last and the least important data is sent first among the FEC encoded data. For example, U.S. patent application Ser. No. 11/423,391, titled “Forward Error Correcting (FEC) Coding and Streaming” (hereinafter “FEC Streaming”), which is incorporated herein for all purposes, describes methods for sending FEC repair data before source data for a source block, thereby allowing a receiver to receive a portion of the source data for the source block and start sending it for example to a media player for play-out even if the receiver joins the stream in the middle of the source block, thus minimizing channel zapping time.

Another concern is to minimize the amount of channel resources used by header data that is used to identify the actual data to be sent. In general, header data is generally overhead that negatively impacts the amount of capacity that is available for delivering data. For example, if 4 bytes of header data are used to identify each 100 bytes of actual data then the header overhead is a significant 4%. It is desirable to minimize the header overhead as much as possible, specifically for both streaming and object delivery applications, but more generally for any data delivery application.

What is desired are methods, processes and apparatus that allow a high quality stream to be delivered over less reliable channels when back channels are not used to enhance reliability when short channel zapping times are required. Minimization of physical resources to achieve a given level of reliability, for example header overheads and FEC oveheads, is also of paramount importance.

### BRIEF SUMMARY OF THE INVENTION

Embodiments present novel methods and processes for sending and receiving streaming data over a channel using FEC codes to provide high quality delivery and to permit short channel zapping times. Novel signaling methods are described that minimize the header overheads needed in such a system for both streaming and object delivery. Novel arrangements of sending and protecting streams are also described.

The following detailed description together with the accompanying drawings will provide a better understanding of the nature and advantages of the present invention.

### BRIEF DESCRIPTION OF THE DRAWINGS

FIG. 1 is a block diagram of a communications system according to one embodiment of the present invention.

FIG. 2 is a drawing exemplifying the components of receiver latency for a known system.

FIG. 3 is a drawing exemplifying the components of receiver latency when FEC repair symbols are sent before the corresponding source symbols from which they are generate.

FIG. 4 is a block diagram illustrating how an embodiment may prioritize data into sub-blocks and map the sub-blocks into a prioritized sending order.

FIG. 5 is a block diagram illustrating how an embodiment may map sub-clocks into physical layer blocks based on mapping integral sub-blocks into each physical layer block.

FIG. 6 is a block diagram illustrating how an embodiment may map sub-clocks into physical layer blocks where an equal amount of sub-block data is mapped to each physical layer block and in which sub-blocks are split sometimes across physical layer blocks.

### DETAILED DESCRIPTION OF THE INVENTION

Embodiments described herein provide for novel methods for signaling the sending of source blocks within multiple physical layer blocks, for both streaming and object delivery applications. These signaling methods comprise methods that use minimal additional overhead, and in some cases no overhead, to signal interleaved source blocks within a physical layer block, signaling how symbols are related to the source blocks from which they are generated, and signaled sending and indications of prioritized data for source blocks. Additional methods are described for organizing and sending streams over one more channels that improve the quality of delivered streams, while minimizing or improving the needed amount of channel resources and receiver power resources needed.

Hereafter, the network carrying data is assumed to be packet-based in order to simplify the descriptions herein, with the recognition that one skilled in the art can easily see how the processes and methods described herein can be applied to other types of transmission networks such as continuous bit-stream networks. Hereafter the FEC codes are assumed to provide protection against lost packets or lost partial data within packets in order to simplify the descriptions herein, with the recognition that one skilled in the art can easily see how the processes and methods described herein can be applied to other types of data transmission corruption such as bit-flips.

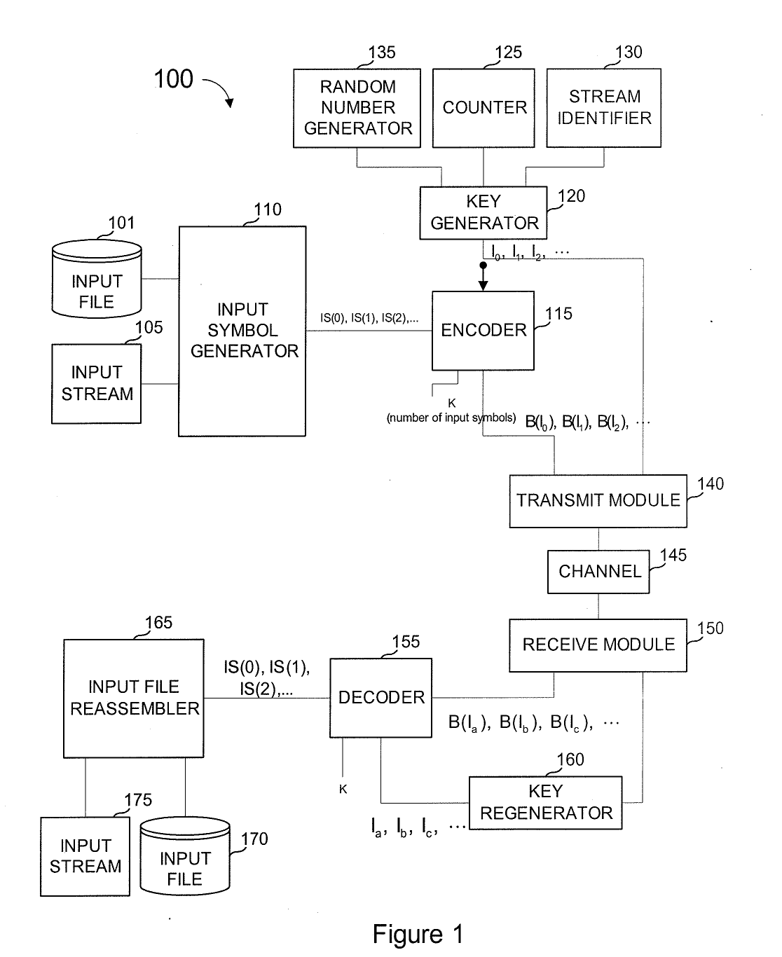

FIG. 1 is a block diagram of a communications system 100 that uses chain reaction coding. In communications system 100, an input file 101, or an input stream 105, is provided to an input symbol generator 110. Input symbol generator 110 generates a sequence of one or more input symbols (IS(0), IS(1), IS(2), . . . ) from the input file or stream, with each input symbol having a value and a position (denoted in FIG. 1 as a parenthesized integer). The possible values for input symbols, i.e., its alphabet, is typically an alphabet of 2^{M} symbols, so that each input symbol codes for M bits of the input file. The value of M is generally determined by the use of communication system 100, but a general purpose system might include a symbol size input for input symbol generator 110 so that M can be varied from use to use. The output of input symbol generator 110 is provided to an encoder 115.

Key generator 120 generates a key for each output symbol to be generated by the encoder 115. Each key is generated according to one of the methods described in Luby I or in Shokrollahi I, or any comparable method that insures that a large fraction of the keys generated for the same input file or block of data in a stream are unique, whether they are generated by this or another key generator. For example, key generator 120 may use a combination of the output of a counter 125, a unique stream identifier 130, and/or the output of a random generator 135 to produce each key. The output of key generator 120 is provided to encoder 115. In other examples, for example some streaming applications, the set of keys may be fixed and reused again for each block of data in a stream.

From each key I provided by key generator 120, encoder 115 generates an output symbol, with a value B(I), from the input symbols provided by the input symbol generator. The value of each output symbol is generated based on its key and on some function of one or more of the input symbols, referred to herein as the output symbol's “associated input symbols” or just its “associates”. Typically, but not always, M is the same for input symbols and output symbols, i.e., they both code for the same number of bits.

In some embodiments, the number K of input symbols is used by the encoder to select the associates. If K is not known in advance, such as where the input is a stream and K can vary between each block in the stream, K can be just an estimate. The value K might also be used by encoder 115 to allocate storage for input symbols.

Encoder 115 provides output symbols to a transmit module 140. Transmit module 140 is also provided the key of each such output symbol from the key generator 120. Transmit module 140 transmits the output symbols, and depending on the keying method used, transmit module 140 might also transmit some data about the keys of the transmitted output symbols, over a channel 145 to a receive module 150. Channel 145 is assumed to be an erasure channel, but that is not a requirement for proper operation of communication system 100. Modules 140, 145 and 150 can be any suitable hardware components, software components, physical media, or any combination thereof, so long as transmit module 140 is adapted to transmit output symbols and any needed data about their keys to channel 145 and receive module 150 is adapted to receive symbols and potentially some data about their keys from channel 145. The value of K, if used to determine the associates, can be sent over channel 145, or it may be set ahead of time by agreement of encoder 115 and decoder 155.

Channel 145 can be a real-time channel, such as a path through the Internet or a broadcast link from a television transmitter to a television recipient or a telephone connection from one point to another, or channel 145 can be a storage channel, such as a CD-ROM, disk drive, Web site, or the like. Channel 145 might even be a combination of a real-time channel and a storage channel, such as a channel formed when one person transmits an input file from a personal computer to an Internet Service Provider (ISP) over a telephone line, the input file is stored on a Web server and is subsequently transmitted to a recipient over the Internet.

Where channel 145 comprises a packet network, communications system 100 might not be able to assume that the relative order of any two or more packets is preserved in transit through channel 145. Therefore, the key of the output symbols is determined using one or more of the keying schemes described above, and not necessarily determined by the order in which the output symbols exit receive module 150.

Receive module 150 provides the output symbols to a decoder 155, and any data receive module 150 receives about the keys of these output symbols is provided to a key regenerator 160. Key regenerator 160 regenerates the keys for the received output symbols and provides these keys to decoder 155. Decoder 155 uses the keys provided by key regenerator 160 together with the corresponding output symbols, to recover the input symbols (again IS(0), IS(1), IS(2), . . . ). Decoder 155 provides the recovered input symbols to an input file re-assembler 165, which generates a copy 170 of input file 101 or a copy 175 of input stream 105.

When used in media streaming applications, source packets forming the source media stream are sometimes collected in groups called source blocks. For example a source block could be a group of source packets spanning a fixed length of time, and for example a Reed-Solomon erasure code could be applied independently to these source blocks to generate repair packets that are sent, together with the original source packets of the source block, to receivers.

At the sender, the source stream can be continuously partitioned into source blocks as source packets arrive, and then repair packets are generated for each source block and sent. It is preferable to minimize the total end-to-end delay added by the use of FEC codes, especially for live or interactive streaming applications, and thus it is preferable if the overall design of the FEC solution is such that source packets are delayed as little as possible at the sender before being sent, and all source and repair packets for a source block are sent with as little total delay as possible. It is also preferable if the rate of the FEC encoded stream is as smooth as possible, i.e., there is as little variability as possible in the FEC encoded stream rate or at least there is no amplification of any variability that already exists in the original source stream, because this makes the FEC encoded stream bandwidth usage more predictable and minimizes the impact on the network and on other possibly competing streams. It is also preferable if the data sent in packets for a source block is spread as uniformly as possible over the period when packets are sent for that source block, since this provides the best protection against burst losses.

At the receiver, if packets are lost or received with errors (which can be detected and discarded, for example, using CRC checks), then, assuming sufficient repair packets have been received, the repair packets may be used to recover one or more of the lost source packets.

In some applications, packets are further sub-divided into symbols on which the FEC process is applied. For some FEC codes, notably Reed-Solomon codes, the encoding and decoding time grows impractical as the number of encoding symbols per source block grows and there is often an upper bound on the total number of encoding symbols that can be generated per source block. Since symbols are generally placed into different packet payloads when used at the application layer, this places a practical upper bound on the maximum length on the encoding of a source block and this is also of course an upper bound on the size of the source block itself.

For many applications, when protection is to be provided over a long period of time or when the media streaming rate is high, it can be advantageous to provide protection over a larger source block size than can be supported by carrying one symbol per packet. In these cases, using shorter source blocks and then interleaving the source packets from different source blocks provides a solution where the source packets from an individual source block are spread out over larger periods of time. Another related method is to form the larger source block from longer symbols that do not fit into packets, and divide the symbols into sub-symbols that can be put into consecutive packets. Using this method larger source blocks can be supported, at the expense of having potentially different sub-symbol loss or corruption patterns for a symbol. However, in many cases where a channel exhibits bursty or strongly correlated corruption, the loss or corruption of sub-symbols comprising a symbol is highly correlated, and thus there is sometimes little degradation of the FEC protection provided when using this method.

### Terminology

### FEC Codes

In this description, we assume that the data to be encoded (source data) has been broken into equal length “symbols”, which can be of any length (down to a single bit). Symbols can be carried over the data network in packets, with a whole number of symbols explicitly carried or implied in each packet. In some cases, it is possible that a source packet is not a multiple of the symbol length, in which case the last symbol in the packet may be truncated. In this case, for the purposes of FEC coding, this last symbol is implicitly assumed to be padded out with a fixed pattern of bits, e.g., zero-valued bits, so that even though these bits are not carried in the packet the receiver can still fill this last truncated symbol out to a full symbol. In other embodiments, the fixed pattern of bits can be placed into the packet, thereby effectively padding the symbols to a length equal to that of the packet. The size of a symbol can often be measured in bits, where a symbol has the size of M bits and the symbol is selected from an alphabet of 2^{M} symbols. Non-binary digits are also contemplated, but binary bits are preferred as they are more commonly used.

The FEC codes we consider for streaming herein are typically systematic FEC codes, i.e., the source symbols of the source block are included as part of the encoding of the source block and thus the source symbols are transmitted. A systematic FEC code then generates from a source block of source symbols some number of repair symbols, and then the combination of the source and repair symbols are the encoding symbols that are sent for the source block. Some of the FEC codes have the ability to efficiently generate as many repair symbols as needed. Such codes are referred to as “information additive codes” and as “fountain codes” and examples of these codes include “chain reaction codes” and “multi-stage chain reaction codes.”

Other FEC codes such as Reed-Solomon codes can practically only generate a limited number of repair symbols from a limited number of source symbols. For these types of codes, a source block can still be relatively large, wherein the source block is partitioned into symbols of large enough size so that the number of source symbols of the source block is at most the upper bound on the practical number of source symbols, and such that the desired number of repair symbols generated from the source block is at most the upper bound on the practical number of repair symbols. In some cases when these symbols are larger than the appropriate size for the transport of physical layer packets, the symbols can be further partitioned into sub-symbols that can be individually carried in such packets. To simplify subsequent descriptions, symbols are typically described as indivisible units, whereas in many cases symbols may be comprised of multiple sub-symbols, wherein the understanding is that symbols could be divided into sub-symbols in the descriptions and the resulting methods and processes would be quite similar to the descriptions using symbols.

There are many other methods for carrying symbols within packets, and although the descriptions below use this example for simplicity it is not meant to be limiting or comprehensive. In the context of the descriptions below, the term “packet” is not meant to be constrained to mean literally what is sent as a single unit of data. Instead, it is meant to include the broader notion of defining a logical grouping of symbols and partial symbols that may or may not be sent as a single unit of data.

There are also forms of corruption of data other than loss of symbols, e.g., symbols that in transmission change their value or are corrupted in other ways, to which the methods described below apply equally. Thus, although the descriptions below will often describe the loss of symbols, the methods apply equally well to other types of corruption and to other types of FEC codes beyond FEC erasure codes, such as FEC error-correcting codes and FEC check-sum codes and FEC verification codes.

### Streaming

For the purposes of providing FEC protection of a source stream, the source stream may be a combination of one or more logical streams, examples of which are a combination of an audio RTP stream and a video RTP stream, a combination of a MIKEY stream and an RTP stream, a combination of two or more video streams, and a combination of control RTCP traffic and an RTP stream. As the source stream arrives at the sender, in a format that for example is a source bit stream, a source symbol stream, or a source packet stream, the sender may buffer the stream into source blocks and generate a repair stream from the source blocks. The sender schedules and sends the source stream and the repair stream, for example, in packets to be sent over a packet network. The FEC encoded stream is the combined source and repair stream. The receiver receives the FEC encoded stream, which may have been corrupted, for example, due to losses or bit-flips. The receiver attempts to reconstruct parts or all of original source blocks of the source stream and makes available to for example a media player these reconstructed parts of the original source stream at the receiver.

For a streaming application, there are several key parameters that are inputs to the design of how to use FEC codes to protect the source stream and several key metrics that are typically of importance to optimize.

Two key input parameters in the design are the protection period and the protection amount. The sender protection period for a source block is the duration of time over which symbols generated from that source block are sent. The protection amount for a source block is the number of FEC repair symbols sent for the source block, expressed as a fraction or a percentage of the number of source symbols in the source block. For example, if the protection period is 2 seconds and the protection amount is 20% and there are 10,000 source symbols in the source block, then the 10,000 source symbols and the 2,000 repair symbols for the source block are sent spread over a 2 second window of time. Both the protection period and the protection amount per source block can vary from one source block to the next. For example, when a source block preferably does not span between certain source packets in a source stream, e.g. when a first packet is the last packet of a Group of Pictures (GOP) in a MPEG2 video stream and a second consecutive packet is the first packet of a next GOP, then a source block might be terminated after the first packet and before the second packet even if this occurs before the end of a protection period. This allows the FEC protection block to be aligned with the video coding block, which can have many advantages, including the advantage that receiver latency due to video buffering and FEC buffering can be minimized. In other applications it can be advantageous for a variety of reasons to always maintain the same protection period and/or source block size for each consecutive source block. In many of the descriptions below for simplicity both the protection period and protection amount are assumed to be the same for each subsequent source block. For those skilled in the art, it should be clear that this is not limiting, as one can easily determine upon reading this disclosure how the processes and methods described herein also apply when either the protection amount or protection period or both vary from one source block to the next, and when source block sizes vary from one to the next.

To simplify some of the subsequent discussions, it is often assumed that source symbols of the original stream arrive at a sender that is to perform FEC encoding at a steady rate, and that once the receiver first makes source symbols available at the receiver, then subsequent source symbols are made available by the receiver at the same steady rate, assuming that in the first source block from which a source symbol is received there is no source symbol loss and that in each subsequent source block the encoding symbol loss is at most the maximum possible to allow successful FEC decoding. This simplifying assumption is not inherent in the operation or design of the processes and methods described subsequently and is not meant to be limiting these processes to this assumption in any way, but is introduced merely as a tool to simplify some of the descriptions of the properties of the processes and methods. For example, for variable rate streams the corresponding condition is that the source symbols are made available by the receiver at the same or close to the same rate as they arrive at the sender.

Some key metrics of importance to minimize include the sender latency, which is the latency introduced by the sender. Minimizing the sender latency is a desirable goal for some applications such as live video streaming or interactive applications such as video conferencing. One aspect of an overall design that helps to minimize the sender latency is for the sender to send source symbols in the same order as they arrive at the sender. Other design aspects that minimize the sender latency are described later.

Another important metric is the channel zapping time. This is the time between when the receiver joins or requests the stream and first starts receiving encoding symbols from the stream until the time when the receiver first makes available source symbols from the stream. In general, it is desirable to minimize the channel zapping time, since this minimizes the memory requirements at the receiver for storing symbols before they are decoded and passed along by the receiver, and this also minimizes the amount of time between when a stream is joined and when the stream first starts becoming available, for example for playback of a video stream.

For many known systems, one important aspect of minimizing the channel zapping time is for the sender to maintain the original sending order of the source symbols. In a subsequent section we describe novel ways of ordering and encoding the source symbols in a block, to apply the FEC codes, and to sending the encoded data for each source block in ways that minimize channel zapping times.

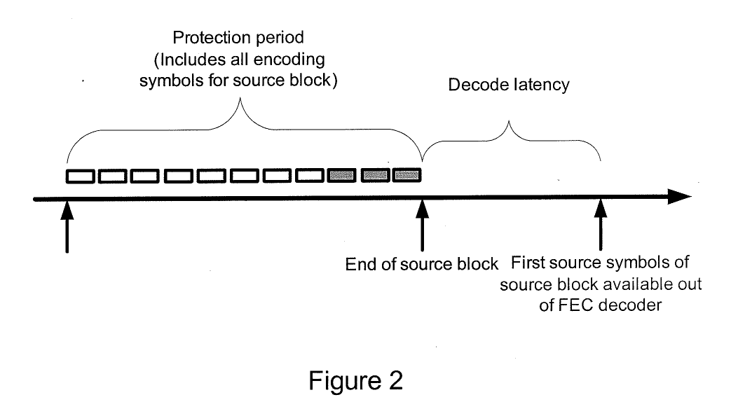

As we now describe, for many known systems the channel zapping time typically comprises multiple components. An example of these components for a stream that is partitioned into sequential source blocks is shown in FIG. 2. FIG. 2 shows a design that might be used in a classical IPTV deployment where there is a single source block per protection period where the repair symbols for each source block are sent just after the source symbols for that source block, and the example shows the case where the receiver joins the stream at the beginning of the source block. The two components of the channel zapping time in this example are the protection period and the decode latency. The receiver protection period is the time during which the receiver is buffering received encoding symbols from the source block. Note that the sender protection period and the receiver protection period are the same if the channel between the sender and receiver does not have any variation in terms of the amount of time it takes each bit, byte, symbol or packet to travel from the sender to the receiver. Thus, in practice the sender protection period may differ from the receiver protection period for the same source block due to network timing variations in delivery. To simplify the description we hereafter assume that the sender protection period and the receiver protection period are the same for each source block, and we use the term “protection period” synonymously for sender protection period and receiver protection period, i.e., we assume that the network delivery time is the same for all data, and we note that one skilled in the art can make the necessary changes to the methods and apparatus described herein to take into account differences in sender and receiver protection periods due to network delivery fluctuations.

The protection period component of the receiver latency is inevitable in these known systems, because even if in the first source block there is no loss of any source symbols, one still has to delay making the source symbols available for at least the protection period in order to ensure smooth source symbol delivery of all subsequent source symbols when there is loss of encoding symbols in subsequent source blocks. During the protection period some or most or all of the FEC decoding of the source block can be occurring concurrently with the reception of encoding symbols. At the end of the protection period, there may be additional FEC decoding that occurs before the first source symbol of the source block is available from the receiver, and this period of time is labeled as the decode latency in FIG. 2. In addition, even after the first source symbol is available there may be additional FEC decoding that occurs before the second and subsequent source symbols of the source block are available. For simplicity, this additional FEC decoding is not shown in FIG. 2, and it is assumed in this example that there are sufficient available CPU resources to decode all source symbols after the first at a fast enough rate.

In these known systems, when the receiver happens to join the stream in the middle of a source block then the channel zapping time can be as small as a protection period plus the decode latency when there is no loss of source symbols from that first partial source block as long as the original sending order of the source packets is maintained by the sender. Thus, for these known systems, it is desirable for the sender to maintain the original sending order of the source symbols.

Another goal of a streaming method is to minimize the FEC end-to-end latency, which is the worst-case overall latency introduced by the use of FEC between when a source packet is ready for streaming at the sender before FEC encoding is applied and when it is available for playback at the receiver after FEC decoding has been applied.

Another goal of a streaming method is to minimize fluctuations in the sending rate when FEC is used. One reason for this goal is that within packet networks, streams with a fluctuating sending rate are more susceptible to packet loss due to congestion or buffer overflow when peaks in the sending rate of the stream coincide with peaks in other traffic at points in the network with limited capacity. At a minimum, the fluctuations in the rate of the FEC encoded stream should be no worse than the fluctuations in the rate of original source stream, and preferably as more FEC protection is applied to the original source stream the fluctuations in the rate of the FEC encoded stream become smaller. As a special case, if the original stream sends at a constant rate, then the FEC encoded stream should also send at a rate that is as close as possible to a constant.

Another goal of a streaming method is to be able to use as simple logic as possible at the receiver. This is important in many contexts because the receiver may be built into a device with limited computational, memory and other resource capabilities. Furthermore, in some cases there may be significant loss or corruption of symbols in transmission, and thus the receiver may have to recover from catastrophic loss or corruption scenarios where when conditions improve there is little or no context to understand from where in the stream reception is continuing. Thus, the simpler and more robust the receiver logic the more quickly and reliably the receiver will be able to start recovering and making available again the source symbols of the source stream from reception of the stream.

When the FEC encoded data to be sent for one source block is sent spread out over a larger period of time interleaved with data sent for other source blocks, the sending of the FEC encoded data for the source block should be sent out as uniformly over time as possible to ensure the best possible protection against loss or corruption in the channel.

The sending of the data for a source block should be such that the receiver can recover the source data of the source block in a determined priority order in a timely fashion.

The data sent for a stream should be sent with as little header information associated with the stream as possible, in order to minimize the header overheads. Preferably no header information is sent with the stream, and some or all of the header information is derived from or already available from other information embedded in the system, and/or some or all of the header information can be inferred from other information, such as the timing of the arrival of the information at the receiver.

In the next section we describe methods, processes and apparatus that meet some or all of these goals.

### Improved Sending and Receiving Methods and Processes

In some cases, the data that is to be delivered as a block can be prioritized. In other cases, the data to be delivered as a block is not necessarily prioritized. In any case, an original stream of data is partitioned into source blocks, FEC repair data is generated for each such source block, and then the encoded data for each such source block, comprising the original source block data and the FEC repair data generated from that source block, is spread out over more time than the original play-out time of the source block (and thus the encoded data for subsequent source blocks are interleaved with one another). In these cases, the FEC codes applied can be erasure codes, which protect the data in the stream against loss of data up to a desired protection amount, although other types of FEC codes are also contemplates, such as FEC codes that are error-correcting codes, or FEC codes that can be used to verify data integrity. In these cases, the more time that the encoded data for each source block of the stream is sent over, called the protection period, and the more equally the encoded data is spread over the protection period, the better the level of protection against packet loss provided by the application layer FEC code.

In one embodiment of the present invention, the sending of the encoded data is sent within a physical channel in equal size pieces, e.g., 120 bytes each, herein called physical layer packets. The physical layer packets may have a physical layer FEC code applied to them in order to protect each physical layer packet from corruption. In some cases, the number of physical layer packets is partitioned into slots of equal numbers of physical layer packets per slot, e.g., 512 physical layer packets. The protocols at the physical layer can sometimes be used to distinguish and uniquely identify the physical layer packets within each time slot. In these cases, FEC symbols can be mapped directly into physical layer packets, and furthermore the identification of which symbols are carried in which physical layer packets can be largely or completely determined by the method of determining the identity of the physical layer packets, alleviating the need or completely removing the need for carrying symbol identification data within each physical layer packet together with the symbol data. In some cases, a partial amount of symbol identification data, or some information about which part of the stream or source block the symbol was generated from, is preferably carried in the physical layer packet together with the symbol. For example, for a 121 byte physical layer packet, there might be 1 byte of such symbol identification data and the symbol size might be the remaining 120 bytes, whereas to completely determine how the symbol was generated from the original source streams might be from a combination of the symbol identification data carried in the physical layer packet together with the symbol and the method that the physical layer packet is uniquely identified, e.g., by the position of the physical layer packet within a frame, and/or by the identifier of the frame containing the physical layer packet, and/or by the timing of the reception of the physical layer packet and/or the frame containing the physical layer packet. For example, the 1 byte identifier an identify the part of the source block that the symbol is from, where for example the different parts of the source block are labeled by which priority the data that portion of the source block is part of, and/or labeled by which stream of multiple streams that a source symbol is from.

Certain improvements can be made to the above process if repair packets are sent in advance of source packets, for example as described in “FEC streaming”. This approach has the cost of injecting additional delay at the sender, since source packets generally are saved in a buffer to be sent after the repair packets. As another example, repair data can be generated from either all or parts of the source block. For example, portions of the repair data may be generated from an entire source block, other parts may be generated from one or more other priority layers of the source block. If there is identifying symbol data carried with a symbol in a physical layer packet or application layer packet that may span more than one physical layer packet, then part of this identifying symbol data for a repair symbol may identify which portions of the source block it is generated from.

### Signaling Methods

In some embodiments, for each symbol, header data associated with the symbol, for example one byte of header data, can be used to signal information about that symbol, e.g., a stream identifier if there is more than one stream, a segment identifier if a source block is to be sent over more than one physical layer block, a sub-block identifier if a source block comprises multiple sub-blocks, a position of the symbol in a source block according to a symbol ordering of the symbols in the source block, etc. In some embodiments, some or all of this header data can be sent with each symbol in physical layer packets. In other embodiments, the header data for each symbol is largely or in total derived from other information, and little or no header data is sent with each symbol in physical layer packets.

Symbols within a Source Block

Preferably, an ordering of symbols of a source block is either explicitly or implicitly determined and is the same ordering at a sender as at a receiver. Certain other preferable properties on the ordering are sometimes beneficial for a streaming or object delivery application. A preferred property, for example, might be that the ordering of the symbols for a source block has all source symbols first in the ordering followed by all repair symbols. Another example is that the symbols are in the order determined by the sub-block structure of the source block, e.g., all symbols associated with the first sub-block of a source block are first in the ordering, all symbols associated with the second sub-block of a source block are second in the ordering, etc. As described earlier, symbols may also comprise multiple sub-symbols.

### ESIs Within a Source Block

An ESI (encoded symbol identifier) is any identifier that determines, in some cases in conjunction with other information such as the number of source symbols in a source block, how the symbol is generated from a source block. An ESI can be explicitly used at a sender to generate symbols or at a receiver to identify and/or recover symbols, or the ESI can be implicitly used. Preferably, the symbols for each source block are ordered in such a way that the sender and receiver can determine an ESI for a given symbol from the position of that symbol within symbol ordering. For example, if the symbol is the j-th symbol in the symbol ordering for a source block, it might be the case that the ESI for that symbol is j, where j is a positive integer.

Preferably, but not exclusively, the mapping between ESIs of the symbols and the symbol ordering can be easily computed by both a sender and a receiver. For example, the consecutive ESIs for the ordered set of symbols might be 0, 1, 2, 3, . . . , j, j+1, etc., i.e., the ESIs are consecutive integers starting at zero and thus the symbol position is the same as the ESI in this case. As another example, the consecutive ESIs for the ordered set of symbols might be 5, 10, 15, 20, . . . , 5*j, 5*(j+1), etc. There are many other ways to determine the mapping of the ESIs to the ordered set of symbols that allow both sender and receiver to determine the ESI for a given symbol given the symbol position within the symbol ordering. Preferably, an ESI sequence that is easy to compute by both a sender and receiver can be used to express a symbol ordering for the symbols associated with a source block.

Physical Layer Packets within a Physical Layer Block

When physical layer packets are sent in physical layer blocks, the ordering of the physical layer packets within a physical layer block can often be determined by the properties of the overall architecture. Furthermore, the differentiation of one physical layer block from another physical layer block can be determined by the sender and receiver, e.g., based on timing information and physical layer signaling. Ordered symbols may be mapped to physical layer packets using a variety of different methods, including linear congruential mapping, or using a mapping that ensures that consecutive symbols are mapped to physical layer packets that will be sent in a time diversified way within the sending of the physical layer block, e.g., each consecutive symbol is mapped to a physical layer packet that is sent in a different time quadrant of the sending of the physical layer block, or consecutive symbols are mapped to physical layer packets that are sent with largely divergent sets of frequencies. The ordered set of symbols to be sent in a physical layer block may be comprised of the symbols associated with the first segment identifier followed by the symbols associated with the second segment identifier followed by the symbols associated with a third segment identifier, etc., where the total number of segment identifiers may be one or more. Among the symbols associated with each segment identifier, the symbols might be ordered by consecutively increasing ESI. A preferable property is that the mapping between ordered symbols and physical layer packets within a physical layer block is well-known (either explicitly or implicitly) and easy to determine by senders and receivers.

As described previously, symbols may be comprised of multiple sub-symbols, wherein each physical layer packet may be able to carry one or more sub-symbols but may not be large enough to carry a symbol. In these cases, the previous description of methods and processes for mapping symbols to physical layer packets can be easily amended to take this further consideration into account. For example, the ESI can be amended to identify not only symbols but also particular sub-symbols within a symbol, e.g., the ESI is both a symbol and a sub-symbol identifier. As another example, the mapping might be such that sub-symbols of a symbol are always sent consecutively, and the mapping from ordered symbols to physical layer packet identifies the physical layer packet that carries the first sub-symbol of the symbol.

In some cases, a large amount of the signaling data may be available in the physical layer blocks, for example the ability to derive the ESIs of symbols or the positions of symbols in the symbol ordering from the positions of the physical layer packets within the physical layer blocks, a physical layer block identifier, and other information carried within the physical layer block header information.

In some embodiments of the present invention, one symbol, either a source or repair symbol, is carried in each physical layer packet together with a minimal amount of header identifying data. An ordered set of symbols for a source block are mapped sequentially to physical layer packets within a physical layer block using a process that is well-known to both sender and receiver. For example, an ordered set of 512 symbols can be mapped to 512 physical layer packets sequentially. The ordering of the symbols can be determined at the sender and communicated to the receiver either explicitly out of band, or preferably implicitly between sender and receiver through pre-determined processes that determine the ordering of the symbols for each block. When symbols from more than one source block are to be mapped to physical layer packets within the same physical layer block, if the source blocks are ordered then the ordering of the symbols with respect to each source block together with the ordering of the source blocks can be used to determine an ordering of all the symbols to be mapped to the physical layer packet within the physical layer block. In other embodiments multiple symbols are carried in each physical layer packet. In yet other embodiments a symbol may span more than one physical layer packet, e.g., when symbols are divided into sub-symbols and each sub-symbol is carried within a physical layer packet. As one skilled in the art will recognize, the processes and methods described herein can also apply to these other embodiments.

In some embodiments, the physical layer block may be a block at a different layer, e.g., a logical block or data, or an application-defined block of data, or a transport block, or a media layer block. Furthermore, physical layer packets may be transport packets, or logical packets, or application packets, or a media layer packet. As one skilled in the art will recognize, there are many essentially equivalent variants of these embodiments.

### Segments

Source and repair symbols associated with a source block can be sent within more than one physical layer block. A segment identifier of a source or repair symbol can be used to indicate which physical layer block the symbol is carried in, relative to the first physical layer block that carries any symbols for that source block, preferably in reverse order. For example, all symbols associated with a source block carried in the last physical layer block that carries any symbols for that source block can have segment identifier 0, whereas the segment identifier for all symbols associated with a source block in each previous physical layer block can have a segment identifier one larger than the segment identifier in the subsequent physical layer block that carries any symbols for that source block. Note that not all consecutive physical layer blocks may carry symbols for a particular source block among the physical layer blocks that carry symbols for that source block, e.g., a first physical layer block may carry symbols for a source block, a next second physical layer block may not carry any symbols for that source block, whereas a next third physical layer block may carry symbols for that source block. In other cases the segment structure of a source block may be signaled by indicating for example a physical layer packet position within the physical layer packet ordering or a physical layer block that is a segment boundary indicator that indicates the end of one segment for one source block and the start of a new segment for another source block. For example, for a physical layer block with 2000 physical layer packets, where the first 500 physical layer packets correspond to a segment from a first source block, the next 600 physical layer packets correspond to a segment from a second source block, and the remaining 900 physical layer packets correspond to a segment from a third source block, the segment boundary indicators 500, 600 might be used to indicate that the segment of the first source block corresponds to the first 500 physical layer packets, the segment of the second source block corresponds to the next 600 physical layer packets, and the segment of the third source block corresponds to the remaining 900 physical layer packets. Alternatively, the segment boundary identifiers may be expressed in units of symbols and may be determined with respect to the ordering of the symbols within a physical layer block.

In some preferred embodiments, within each physical layer block there is at most one source block associated with each segment identifier, and thus a segment identifier can be used to uniquely distinguish the symbols from different source blocks, and thus in these cases a segment identifier also is used as a source block identifier to differentiate the symbols carried within a physical layer block. In other embodiments, source block identifiers for the symbols are carried by other means, e.g., by including a source block identifier in the header data associated with each symbol, or by including a source block identifier in the header data associated with each physical layer block. There are other variations wherein a source block identifier is not necessarily carried in the headers of physical layer blocks, but could be carried in other places instead, e.g., a control data stream, in a separate physical layer block that contains header information for multiple physical layer blocks, or sent via another network. One skilled in the art will recognize that many other similar variations.

### Sub-Blocks

An encoded or un-encoded source block may comprise more than one sub-block, for example the sub-blocks correspond to different source and repair symbols associated with a source block that correspond to logically associated parts of the symbols. For example, a first set of source and/or repair symbols comprising a first sub-block may correspond to a portion of the source block that can be used to render a low-resolution video of the portion of the video associated with the source block, whereas a second set of source and/or repair symbols comprising a second sub-block may be able to render a higher resolution video of the portion of the video associated with the source block when used in conjunction with some or all of the first sub-block. As another example, a sub-block identifier may identify some or all of the repair symbols associated with a source block, or a sub-block identifier may identify some or all of the source symbols associated with a source block. In some cases, a sub-block identifier may be signaled by explicitly labeling each sub-block with a number. For example, the first sub-block of a source block may have the sub-block identifier 0, whereas the second sub-block of a source block may have the sub-block identifier 1. In other cases the sub-block structure may be signaled by indicating for example an ESI or symbol position within the symbol ordering that is a sub-block boundary indicator that indicates the end of one sub-block and the start of a new sub-block within the ESI or symbol ordering. For example, for a source block with 900 source symbols and 100 repair symbols, where the ESIs of the symbols are consecutive integers starting at zero and where the first sub-block comprises the source symbols and the second sub-block comprises the repair symbols, the sub-block boundary indicator 900 might be used to indicate that the first sub-block corresponds to the symbols with ESIs from 0 to 899 and the second sub-block starts with the symbol with ESI 900. The sub-block identifier of a source or repair symbol indicates of which sub-block the symbol is part.

Header Data Sent with Each Symbol Method

In one embodiment, the header data associated with each symbol that is to be sent together with the symbol in a physical layer packet comprises a segment identifier, a sub-block identifier and an ESI. For example, if the number of possible segment identifiers is 8 and the number of possible sub-block identifiers is 8 and the number of ESIs is 1024 then 16 bits or equivalently 2 bytes of header data are sufficient for each symbol. Within each physical layer packet within a physical layer block, the contents of the physical layer packet comprises a symbol together with the header data associated with that symbol, where the header data comprises a segment identifier and a sub-block identifier.

In this embodiment, a receiver might process received physical layer packets within a physical layer block as follows. Upon reception of physical layer packets within a physical layer block, the receiver determines from the header data associated with a symbol within each physical layer packet that it is able to read. From the header data the receiver can determine a segment identifier, a sub-block identifier and an ESI for the symbol contained within the physical layer packet. From the segment identifier the receiver can determine which source block the symbol is associated with among the possible source blocks. From the sub-block identifier the receiver can determine which sub-block the symbol is associated with among the possible sub-blocks of the source block. From the ESI the receiver can determine the relationship of the symbol to the source block and to the sub-block of the source block, where the ESI can be used to determine the symbol position of the symbols within the source block, and/or to be used in FEC decoding to recover missing source symbols from received repair symbols and other source symbols.

The receiver can then, based on this information, decide on certain actions. For example, the receiver may use the sub-block data associated with symbols for different purposes. For example, the sub-block data may be used partially to determine how to FEC decode to recover some or all of a source block. The sub-block data may for example also be used to determined what portions of data should be passed on to an upper layer application, e.g., a multimedia player process within the receiver, in order to support higher level functionality within the receiver, e.g., to determine which portions of a recovered source block to pass on as a whole to a multimedia player for play-out of multimedia. For example, when a receiver receives a first physical layer block, a portion of the symbols associated with the first segment identifier may be associated with a first sub-block which may be passed on to a multi-media player for play-out of a low quality video portion associated with the source block associated with the first segment identifier. The receiver may also decide to save the extracted and/or recovered symbols associated with source blocks with segment identifiers other than the first segment identifier in order to combine them with symbols for the same source blocks received in subsequent physical layer blocks and combine these symbols for FEC decoding and/or for passing on to a media player, perhaps in units of sub-blocks of symbols or sets of sub-blocks of symbols.

As one skilled in the art will recognize, there are variants and combinations of the above embodiments. For example, the header data for a symbol that is sent with the symbol may include segment identifiers and sub-block identifiers, but not an ESI. As another example of a variant, only the ESI is sent in the header data with the symbol, and other data such as a segment identifier or sub-block identifier if used is determined from other data.

As another example of a variation, the header data associated with each symbol may not include a sub-block identifier. In this case a sub-block identifier may for example be determined implicitly by the derived ESIs, or the sub-blocks coincide with the segments of a source block, or sub-blocking is not used.

As another example of a variation, the header data associated with each symbol may comprise may not include a segment identifier. In this case the segment identifier may for example be determined implicitly by allocating a fixed amount of physical layer packets within each physical layer block, or sub-blocks coincide with segments, or segmenting is not used.

As another example of a variation, the header data associated with each symbol may also include a stream identifier. In this case, the stream identifier may determine which stream among a small number of streams a symbol is associated with, e.g., an audio stream or a video stream. Note that a stream identifier may be scoped by other identifiers, e.g., if the streams are logically connected, such as audio and video streams for the same program segment, then for example a sub-block identifier may scope some or all of the stream identifiers. Note that the stream identifier may also scope other identifiers, e.g., if the streams are logically independent, such as audio/video streams for different program segments, then for example a stream identifier may scope some or all of the sub-block identifiers.

No Header Data Sent with Each Symbol Method

In another embodiment, there is no header data associated with a symbol that is carried in a physical layer packet. Instead, some minimal data can be carried within the header data of the physical layer block. The minimal data can include, for example, a segment table, where each row of the segment table corresponds to a segment identifier which comprises the number of symbols of the segment for a source block that are carried in that physical layer block and the ESI of the first symbol in the symbol ordering for that segment of a source block among all of the symbols of the segment for the source block that are carried in that physical layer block. The number of symbols in the segment may not be included in some embodiments, for example because the number of symbols in each segment is always the same across all physical layer blocks.

In some embodiments, the segment table may instead be a source block table, in cases where the same segment identifier is to be used for two or more source blocks within a same physical layer block.

The minimal data can also include, for example, a sub-block table, which indicates which sub-blocks the symbols for each source block are carried within the physical layer block. There are many forms for this sub-block table, for example the sub-block information may be appended to each row of the appropriate segment identifier row in the segment table, or as another example the sub-block information may be stored in a separate table. In some embodiments, the sub-block table may not be included, for example because either sub-blocking is not used or because the sub-blocking signaling is handled at a higher application layer.

In this embodiment, a receiver might process received physical layer packets within a physical layer block as follows. The receiver reads and stores the segment table and/or sub-block table from the physical layer block header data. From the segment table, the receiver can determine the number of symbols and initial ESI associated with each segment of a source block for which there are symbols carried with the physical layer block. From the physical layer identification of the position of a physical layer packet that carries a symbol, from the segment table containing the number and initial ESI associated with each segment, and from the mapping of the combined ordered set of symbols from all the segments of the source blocks contained in the physical layer block to the physical layer packets, the receiver can determine the ESI of the symbol and with which source block the symbol is associated. From the sub-block table, in a similar fashion the receiver can determine with which sub-block of the source block the symbol is associated.

From the ESI the receiver can determine the relationship of the symbol to the source block and to the sub-block of the source block, where the ESI can be used to determine the symbol position of the symbols within the source block, and/or to be used in FEC decoding to recover source symbols that are not received from received repair symbols and other source symbols.

The receiver can then, based on this information, decide on certain actions, including those described above for the “Header data sent with each symbol” method described herein.

As one skilled in the art will recognize, there are many variations of the above. As one example of a variation, the header data associated with each symbol may comprise the sub-block identifier, for example using a portion of one byte of each physical layer packet for this purpose. This might be preferable in some cases, as the sub-block structure spans an entire source block, whereas the sending of the data for the source block may be over several physical layer blocks, and thus carrying a sub-block identifier within the header data sent with each symbol may allow a receiver that joins the channel in the middle of the transmission of a source block to quickly understand the sub-blocking structure of the source block.

As another example, sub-blocking might not be used.

As another example, the header data associated with each physical layer packet may for example be sent as separate data within the same physical layer block or be communicated by other means to the receiver, for example sent within a control channel that is available to the receiver, or as another example sent in a separate physical layer block that contains header information for multiple physical layer blocks, or as another example sent via another network.

As another example, the header data associated with each symbol may also include a stream identifier. In this case, the stream identifier may determine which stream among a small number of streams a symbol is associated with, e.g., an audio stream or a video stream. Note that the stream identifier may be scoped by other identifiers, e.g., if the streams are logically connected, such as audio and video streams for the same program segment, then for example a sub-block identifier may scope some or all of the stream identifiers. Note that the stream identifier may also scope other identifiers, e.g., if the streams are logically independent, such as audio/video streams for different program segments, then for example a stream identifier may scope some or all of the sub-block identifiers. A stream identifier may also be included within the header data for a physical layer block in a format similar to that described above for segment identifiers and sub-block identifier, in which case it may not be necessary to include a stream identifier in the header data associated with each symbol in order to communicate the stream structure to a receiver.

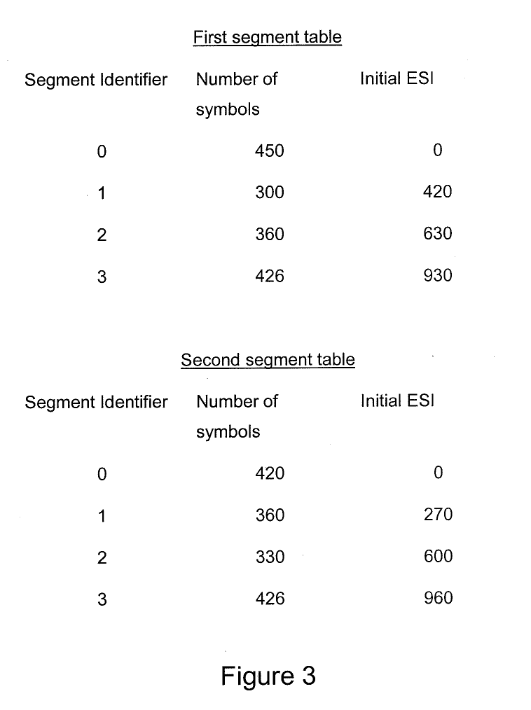

As an example, suppose number of segments per source block is 4, number of sub-blocks is 3, the number of physical layer packets per physical layer block is 512, and three symbols of size 100 bytes each is included in each physical layer packet of 300 bytes, and thus each physical layer block contains 3*512=1536 symbols. Then, a first segment table for a particular first physical layer block and second segment table for a second physical layer block might be as shown in FIG. 3, where the second physical layer block is consecutively sent after the first physical layer block. In this example, the segment identifier might not be explicitly carried in the segment table, but instead might be implied by the row number in the table, i.e., row j corresponds to segment identifier j.

In the first segment table, the number of symbols for the segment with identifier 0 is 450, which would be carried by the 150 physical layer packets the first 450 symbols are mapped to according to the ordered symbols to physical layer packet mapping. The ESIs for the symbols with segment identifier 0 are the consecutive integers ranging from 0 up to 449 in this example. The number of symbols for the segment with identifier 1 is 300, which would be carried by the 100 physical layer packets after the first 150 physical layer packets the 300 symbols are mapped to according to the ordered symbols to physical layer packet mapping. The ESIs for the symbols with segment identifier 1 are the consecutive integers ranging from 420 up to 719 in this example.

In the second segment table, the number of symbols for the segment with identifier 0 is 420, which would be carried by the 140 physical layer packets the first 420 symbols are mapped to according to the ordered symbols to physical layer packet mapping. Note that the source block with segment identifier j in the first segment table can be the same as the source block with segment identifier j+1 in the second segment table, for j=0, 1, 2. Thus, the initial ESI for the segment with identifier j in the first segment table is under this mapping the sum of the initial ESI and the number of symbols of the segment with identifier j+1 in the second segment table.

There are other variations wherein the data is not necessarily carried in the headers of physical layer blocks, but could be carried in other places instead, e.g., a control data stream, in a separate physical layer block that contains header information for multiple physical layer blocks, or sent via another network. One skilled in the art will recognize that many other similar variations of the above-described method.

### Mappings to and From FEC Payload ID

For many application layer FEC codes described in standards, for example as described in IETF RFC 5052 (Internet Engineering Task Force Request for Comments 5052) and IETF RFC 5053 (Internet Engineering Task Force Request for Comments 5053), typically associated with symbol or group of symbols or group of sub-symbols sent in an application layer packet is an FEC Payload ID (Identifier). For the simplest case, when the FEC Payload ID is associated with a symbol, the FEC Payload ID comprises the source block number that the symbol was generated from, the ESI of the symbol, and in some cases the initial ESI of the repair symbol with the smallest associated ESI (and this initial ESI can be viewed as a sub-block identifier, identifying the source symbols are part of a first sub-block and the repair symbols as part of a second sub-block).

In some of the methods and processes described above, the FEC Payload ID is not sent with each symbol, and instead other means are described that minimize the amount of header data that is sent with each symbol in order to maximize channel capacity. It is useful in some cases at a sender to translate the sending format from one using an FEC Payload ID to one using the means described above for conveying this information to a receiver. It is also useful in some cases at a receiver to translate the sending format from one using the means described above for conveying this information to a receiver to one using an FEC Payload ID. For example, there might be already developed software that uses the FEC Payload ID for identifying symbols, and it can be convenient to take an output stream of symbols and associated header data generated using this software to produce an output stream of symbols and associated data compatible with the sending format using the means described above.

The mapping methods to and from the FEC Payload ID format can be easily derived from the description provided above.

### Sending Arrangements to Optimize Channel Zapping

For a prioritized stream that is to be sent over a channel, where data to be sent is divided into different physical layer blocks, for example frames or super-frames, the symbol data that is to be sent for a source block can be interleaved over multiple such physical layer blocks in a prioritized manner, in the reverse order of their priority. For example, as described in “FEC streaming”, the repair data for a source block can be sent prior to the source data for a source block in order to reduce, in the context of these descriptions, channel zapping time. The data comprising data at a given priority level for a source block can be grouped together into a sub-block. For example, continuing the example described above, the repair symbols can be considered to be a lower priority sub-block, and the source symbols a second higher priority sub-block, and thus the lower priority sub-block can be sent prior to the higher priority sub-block.

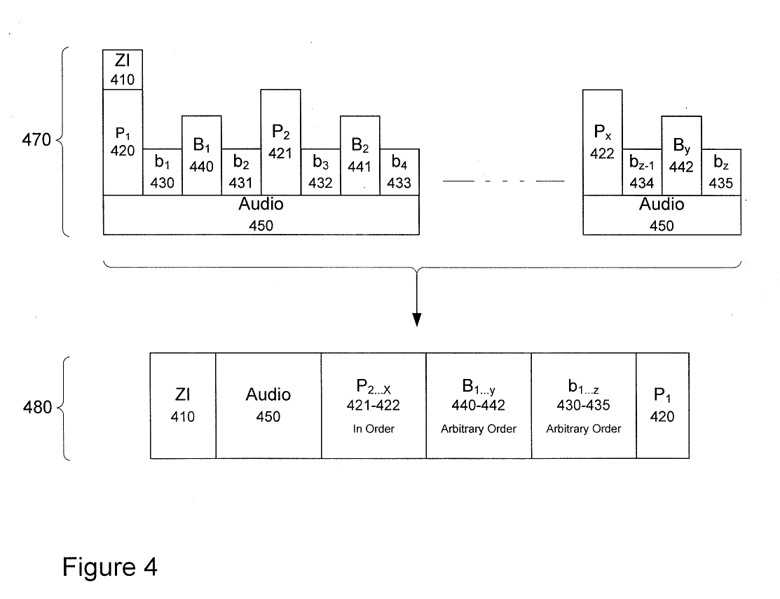

FIG. 4 illustrates an example of how an embodiment may prioritize data into sub-blocks and map the sub-blocks into a prioritized sending order. In FIG. 4, data stream 470 is represented with various blocks and sub-blocks of data. For example, data stream 470 is shown with an audio block 450 and various video blocks such as an I-Frame (ZI) 410 and various sub-blocks of symbol data such as P₁-Pₓ 420-422, b₁-b_{z} 430-435, and B₁-B_{y} 440-442. In FIG. 4, P₁ 420 represents the highest priority sub-block in the stream, followed by b₁-b_{z} 430-435, B₁-B_{y} 440-442, P₂-Pₓ 421-422, audio block 450, and I-Frame (ZI) 410, respectively. Given these priority levels, the blocks and sub-blocks of the stream can be arranged as illustrated by sending arrangement 480. The lowest priority block (ZI 410) can be transmitted to a receiver at the beginning of a transmission, while the highest priority data (P₁ 420) can be sent last. Additionally, dependencies between the various sub-blocks can also be taken into account when creating the prioritized sending order. For example, according to some embodiments, sub-blocks b₁, B₁, and b₂ may be dependent on P₁. In these embodiments, it may be advantageous to transmit these dependent sub-blocks before P₁ is transmitted. Thus, as soon as P₁ is received, all of the data in P₁ and all of its dependent sub-blocks can be made available quickly at a receiver. Once a sending arrangement has been determined, the sending arrangement can be used to divide the data into different physical layer blocks accordingly.

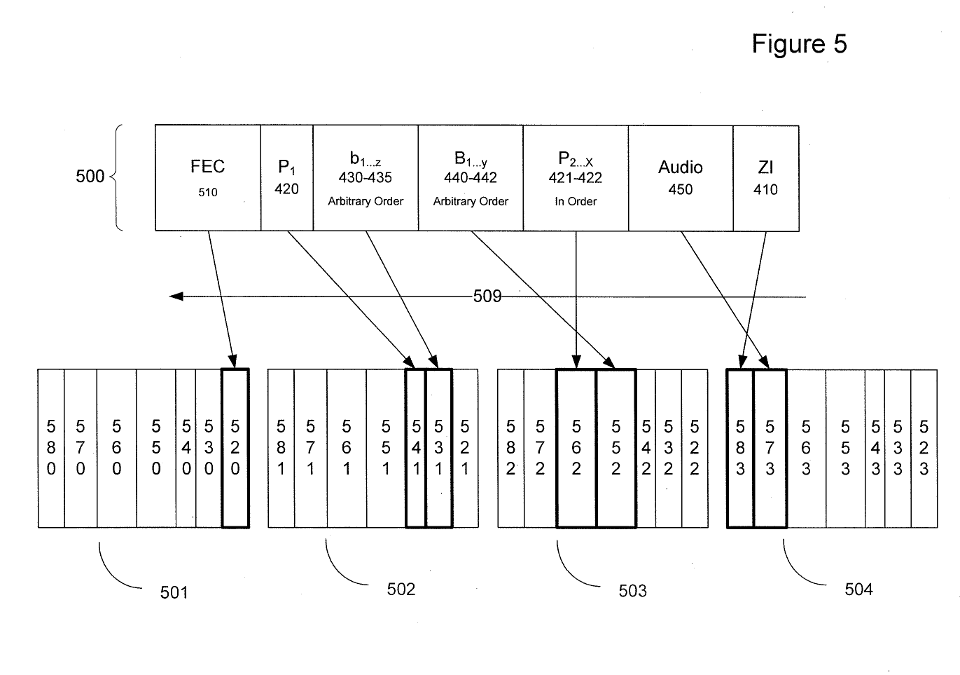

One method for mapping prioritized sub-blocks into physical layer blocks to map sub-blocks into each physical layer block. FIG. 5 shows an example of one embodiment of this method. FIG. 5 shows a set of data 500 broken up into various physical layer blocks 501-504. The blocks in FIG. 5 are represented as being transmitted in the direction indicated by arrow 509. For example, physical layer block 501 is transmitted ahead of physical layer block 504 (and thus is transmitted before physical block 504), and within physical layer block 501, section 580 is transmitted ahead of section 520. As illustrated in FIG. 5, some of the data 500 is placed into each physical layer block 501-504. For clarity purposes, each segment of data in the data 500 is only shown placed into one of the physical layer blocks 501-504 even though each segment is placed into a corresponding section of each physical layer block. FEC data 510 is placed into the physical layer blocks at 520-523; P₁ data 420 is placed into the physical layer blocks at 540-543; b₁-b_{z} data 430-435 is placed into the physical layer blocks at 530-533; B₁-B_{y} data 440-442 is placed into the physical layer blocks at 550-553; P₂-Pₓ data 421-422 is placed into physical layer blocks at 560-563; audio data 450 is placed into physical later blocks at 570-573; and I-Frame (ZI) 410 is placed into physical layer blocks 580-583. One advantage of mapping sub-blocks into physical layer blocks in the manner illustrated in FIG. 5 is that the play-out behavior at a receiver will be more predictable because segments of each priority group will be contained in each physical layer block. However, various segments within each physical layer block will typically be different sizes, because the various priority levels will typically contain different amounts of data. This can lead to potential performance issues at the receiver due to more complicated processing at the receiver to unpack the data, and there may be issues with stat-muxing due to the different segment sizes.

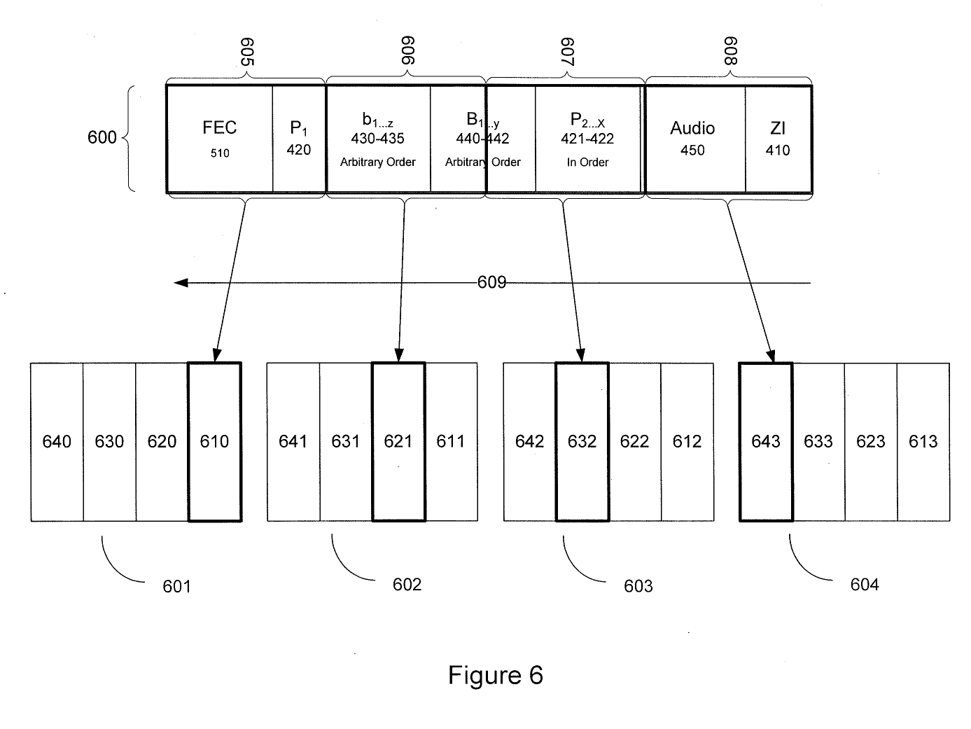

Another method is to spread the symbol data as equally as possible over the different physical layer blocks, as this generally provides the best protection against channel impairments. FIG. 6 shows an example of one embodiment of this method. FIG. 6 shows a set of data 600 broken up into various physical layer blocks 601-604. The blocks in FIG. 6 are represented as being transmitted in the direction indicated by arrow 609. For example, physical layer block 601 is transmitted before physical layer block 604 (and thus is transmitted before physical block 604), and within physical layer block 601, section 640 is transmitted before section 610. As illustrated in FIG. 6, the various data priorities in the symbol data 600 have been grouped together in blocks 605-608. These blocks 650-608, in turn, have been mapped into physical layer blocks 601-604 in equal amounts. For clarity purposes, each segment of data 600 is only shown placed into one of the physical layer blocks 601-604 even though each segment is placed into a corresponding section of each physical layer block. For example, block 605 is mapped into 610-613; block 606 is mapped into 620-623; block 607 is mapped into 630-633; block 608 is mapped into 640-643. As a result of the mapping illustrated in FIG. 6, some sub-blocks are split between groupings. For example, data from data segment B₁-B_{y} 440-442 may be included in both blocks 606 and 607. Additionally, a given physical block may not contain any data from particular priority. For example, block 601 may not contain any FEC 510 data at 610 while block 604 may not contain any data from P₁ 420 at 613. One advantage of the method illustrated in FIG. 6 is that since the segments of the physical layer blocks are the same size, the receiver will require less processing to unpack the segments. This may result in improved receiver performance. Additionally, the uniform segment size makes stat-muxing easier. However, since there may not be any guarantees as to the exact priority levels that will be contained in any given physical layer block, the play-out behavior at the receiver will be less predictable.

One concern while mapping data is that enough of the high priority data for the source block is sent in the first physical layer block in order to allow the receiver to start play-out as soon as this high priority data is received. One method for achieving this is to prioritize the data in the encoded or un-encoded source blocks in such a way that the amount of high priority data is at most a fraction of 1/N of the total amount of data to be sent for the source block, wherein N is the number of physical layer blocks over which the data is to be sent for the source block, in the case where high priority data for some source block should be available after a receiver receives a first physical layer block. In general, if the requirement is that the first J priorities of data need to be available for some first source block after the receiver receives K physical layer blocks, then this can be achieved if the fraction of data in the first J priorities is at most K/N.

An example of a preferred partitioning strategy is the following, which can be used whether or not the above method is employed. Suppose the sent data for a source block is to be sent within N physical layer blocks, where the sent data comprises the source symbols for the source block and FEC repair symbols, if any, generated from the source block that is to be sent. Suppose the sent data for a source block is divided into K priorities, where the fraction of the sent data with priority j is P_j for j=1, . . . , K.

As described above, the sent data with a priority j can be grouped into a sub-block, call it sub-block j. Then, the fraction of the sent data sent in the last physical layer block can be the maximum of P_{—}1 and 1/N, i.e., all of the data in the highest priority sub-block 1 and possibly some of the remaining data is sent in the last physical layer block N. Let M_{—}1 be this maximum, and let L_{—}1=1−M_{—}1 be the remaining fraction of data to be sent in physical layer blocks N−1, . . . , 1 after a fraction M_{—}1 of the data is sent in the last physical layer block N. Then, the fraction of the sent data sent in physical layer block N−1 can be the maximum of P_{—}1+P_{—}2−M_{—}1 and 1/N−1, i.e. all of the highest priority sub-block and second highest priority sub-block is sent in the last two physical layer blocks, and possibly some of the remaining data as well. This is assuming that the data of the first two priorities is to be played out at the receiver after two physical layer blocks have been received.

This method can be extended to determine which sent data to send in each physical layer block. This method can also be extended to the case when the receiver requirements for the receiver to play-out sent source block data is different, e.g., the priority 2 sent data is to be played out after receiving three physical layer blocks instead of after two physical layer blocks. The methods above might also be modified by the requirement to multiplex many different streams or bundles of streams over the same physical channel, where he amount of space available in each physical layer block is used to determine how much of each priority of sent data for each stream or bundled streams is to be sent in each block.

Note that the priorities described above need not describe a complete ordering, i.e., the priorities may be a partial order, in which case there are choices for which order to place the prioritized data, and in fact prioritized data that is incomparable in terms of priority may be mixed together in the sending order, in some embodiments.

As described above, implementing any of these proposed sending arrangements can be accomplished using any of the improved sending and receiving methods and processes described herein, e.g., ESIs, including header data sent with each symbol, not header data sent with each symbol, etc.

### Partial FEC Coding of a Source Block

FEC repair data can be generated from an entire source block, and provides capability to recover the entire or significant portions of a source block if enough source symbols from the source block plus repair symbols generated from the source block are received. FEC repair data may be generated from only parts of the source block, e.g., one set of FEC repair data may be generated from a first portion of the source block, a second set of FEC repair data may be generated from a second portion of the source block. As an example, the second portion of the source block may include the first portion of the source block plus some additional parts of the source block. Suppose the source symbols for a source block are divided into a low priority source sub-block and a high priority source sub-block. Then, a first sub-block of FEC repair symbols can be generated from the high priority source sub-block, and a second sub-block of FEC repair symbols can be generated from the concatenation of the low priority source sub-block and the high priority source sub-block. The sending order of the sub-blocks then could be: second sub-block of FEC repair symbols, low priority source sub-block, first sub-block of FEC repair symbols, high priority source sub-block. In this case, if a receiver receives only all or part of the high priority source sub-block then it can try to play this out immediately, if there is not too much corruption. If a receiver receives all or part of the first sub-block of FEC repair symbols and the high priority source sub-block then the receiver can try to recover the high priority source sub-block using the first sub-block of FEC repair symbols if there is not too much corruption. If a receiver receives all or part of the low priority source sub-block, the first sub-block of FEC repair symbols and the high priority source sub-block then the receiver can try to recover corrupted parts of the high priority source sub-block using the first sub-block of FEC repair symbols and then send a media player the received portions of the low priority source sub-block and the recovered portions of the high priority source sub-block. If a receiver receives all or portions of all four sub-blocks, then the receiver can use all of the FEC repair symbols to recover all of the source symbols.

Note that the above methods can be preferable to providing FEC protection over each sub-block separately, e.g., having the second sub-block of FEC repair symbols protect the entire source block instead of just the low-priority source sub-block can be preferable. For example, suppose each of the two source sub-blocks comprise 100 source symbols each, and each of the two FEC repair sub-blocks comprise 50 repair symbols each. Using the methods described above can allow recovery of the entire source block even when 60 of the source symbols from the high priority source sub-block are lost and 30 of the source symbols from the low priority source sub-block are lost, whereas if the two source sub-blocks are protected independently by the two FEC repair sub-blocks then recovery of the high priority sub-block is not possible (lost 60 source symbols of the sub-block, there are only 50 repair symbols that protect the sub-block). Such FEC protection can be for example realized using Reed-Solomon codes, where experiments show that Reed-Solomon codes exhibit almost ideal recovery properties when used in the ways described above to protect overlapping sub-blocks.

These methods are also useful for protecting in case protection across too long of a time period causes entire time periods of data received to be wiped out occasionally. Instead, providing FEC protection over short blocks, and then also providing FEC protection over longer blocks that include the short blocks, can be preferable. This way, if outage with not too much loss in surrounding time periods, then FEC protection across short blocks may allow those to be recovered, whereas additional FEC protection across longer blocks allows more loss to be over longer time periods.

### Receiving Multiple Physical Layer Block Streams

For streaming applications where logically connected streams are sent over a single stream of physical layer blocks, the entire physical channel might be composed of multiple such physical layer block streams. For example, each physical layer block stream might be 256 Kbps, or 1 Mbps, whereas there might be 50 such streams so that the entire available physical channel might be 12.5 to 50 Mbps in this example.

Typically a receiver may receive one of the streams of physical layer blocks at a time, due to a variety of different reasons including power issues and memory issues. However, there may be advantages for the receiver to receive more than one stream of physical layer blocks. For example, if the receive is receiving all such streams, then channel zapping from one stream to another can occur almost instantaneously, and the new stream that the receiver moves to can be played out from the beginning at the highest quality level, because all the data for the new stream has been arriving for a period of time before when the receiver changes channels to that stream. This is true even if the streams are protected using FEC protection with a long protection period, or if the streams are video encoded in such a way that is highly compressed, e.g., when refresh frames in a video stream, sometimes called I-frames, sometimes called IDR-frames (Independent Data Refresh frames), are sent infrequently due to their large size. This typically means that the time spanned by a GOP (Group of Pictures) can be rather large in a highly compressed video stream. For example, the GOP duration for a video stream might be 10 seconds, and FEC protection might be provided to protect the entire GOP of 10 seconds. In this case, without using some of the methods described above where high priority data from the stream is displayed as quickly as possible and then lower and lower priority data is also displayed to enhance the play-out quality as the stream play-out progresses, if a receiver were receiving only one channel at a time the channel zapping time could be as high as 10 seconds, whereas if the receiver is receiving all channels then the channel zapping time could be almost instantaneous.

There are some optimizations possible when considering a solution where a receiver is concurrently receiving more than one stream of physical layer packets. For example, the receiver only needs to FEC decode, e.g., perform either error-correction decoding or erasure protection decoding, only the streams that are being currently being sent to for example the media player for play-out. The data for other streams can be stored, and only FEC decoded if the receiver changes channels, and then the FEC decoding can occur very quickly on the data that has already been received for the new channel to start the media play-out almost immediately.

As another possible optimization, when a receiver is receiving only one stream at a time, there may be redundant data that is included in the stream that is not needed if the receiver had previous parts of the stream available for play-out when the receiver first joins the stream. Examples of such redundant data might be low quality video IDR frames that are included very frequently in a video stream solely so that a receiver can join a stream and start playing out some video almost immediately, even if it is at degraded quality. If the receiver had previous portions of the stream, including a high quality IDR frame and all subsequent frames sent earlier, then there would be no need to include the frequent low quality IDR frames. The low quality IDR frames can use a significant amount of the available bandwidth, e.g., if each low quality IDR frame is 3 KB and they are sent each second in a 256 Kbps stream, then the low quality IDR frames use over 9% of the available bandwidth. Sending the low quality IDR frames is not necessary if the receiver is receiving data for the stream that the receiver changes to prior to the channel change to that stream.

One drawback of listening to multiple streams of physical layer blocks is that it uses more power at the receiver than listening to a single stream. Additionally, more memory and other resources are needed to store the data received from multiple streams than a single stream. There are some methods that can be used to minimize these drawbacks. One such method is to organize the logic and/or the data globally over the available streams in such a way that a receiver needs to receive only a few streams at a time in order to achieve the above benefits.

For example, if there is logic that can predict which streams a receiver might likely change channels to, the logic can be such that the receiver is receiving these likely channels in advance of an actual change to that channel.

As another example, the data in the physical layer block streams might be organized such that there is one physical layer block stream that carries all of the IDR frames for all the other video streams, call it the IDR stream, and then each other physical layer block stream carries all of the data for one of the video streams except for the IDR frames for that video stream. In this example, a receiver might receive the current physical layer block stream for the video stream that is currently being played out by the media player while at the same time (either always or intermittently when appropriate) receive the IDR stream. Thus, the receiver can have available the IDR frames for all or some of the video streams, which it can use to either play-out when displaying information about all or some of the video streams available in a thumb-nail channel guide mode, or use to start displaying a new video stream when a channel change is made at the receiver. The IDR stream may be received at all times, or may be received intermittently, e.g., only receive physical layer blocks from the IDR stream that contain IDR-frames for the currently playing video stream. In all cases, FEC protection can be provided on each physical layer block stream if desired. One advantage of these methods is that the receiver receives at most two physical layer block streams at any point in time and yet gains all or most of the advantages of receiving all the physical layer block channels concurrently.

While the invention has been described with respect to exemplary embodiments, one skilled in the art will recognize that numerous modifications are possible. For example, the processes described herein may be implemented using hardware components, software components, and/or any combination thereof. For example, the methods described herein could be embodied on a computer-readable medium, such as a CD-ROM, DVD, etc., comprising computer-executable code that can direct a processor of a computer to carry out the methods. Thus, although the invention has been described with respect to exemplary embodiments, it will be appreciated that the invention is intended to cover all modifications and equivalents within the scope of the following claims.

What is claimed is:

1. An electronic delivery system for delivering data streams over a broadcast channel, wherein the broadcast channel is a channel for conveying signals from one or more sources to a plurality of receivers, wherein each receiver attempts to receive substantially the same signal, the electronic delivery system comprising:
a sender system that sends data for the data stream within physical layer packets of physical layer blocks, wherein indications of how the sent data is related to the data stream are based at least in part on the physical layer blocks.

2. The electronic delivery system of claim 1 wherein indications of how the sent data is related to the data stream are based at least in part on information in headers of the physical layer blocks, wherein the sender system configures the headers of the physical layer blocks to include the indications.

3. The electronic delivery system of claim 1, wherein indications of how the sent data is related to the data stream are based at least in part on information in headers of the physical layer packets.

4. The electronic delivery system of claim 1, wherein the sent data is organized into symbols within source blocks of data, and wherein the indications comprise indications of how a symbol is generated from a source block and indications of an association between a symbol and a source block.

5. The electronic delivery system of claim 4, wherein the indications are encoding symbol identifiers, wherein the encoding symbol identifiers are at least partially carried in headers of physical layer blocks.

6. The electronic delivery system of claim 4, wherein the indications are encoding symbol identifiers, wherein the encoding symbol identifiers are carried in a control data channel.

7. The electronic delivery system of claim 4, wherein the association between symbols and source blocks can be largely determined from headers of physical layer blocks.

8. The electronic delivery system of claim 4, wherein the sent symbols of data include FEC repair data generated from source blocks.

9. The electronic delivery system of claim 4, wherein more than one logical stream of data is sent within a single stream of physical layer blocks.

10. The electronic delivery system of claim 4, wherein sent symbols of data are sent over more than one stream of physical layer blocks.

11. The electronic delivery system of claim 4, wherein indications of how the sent symbols of data is related to the stream or object data are at least partially carried in physical layer packets that carry the symbols of sent data.

12. The electronic delivery system of claim 4, wherein the data sent for a source block is organized into different sub-blocks of different priorities.

13. The electronic delivery system of claim 12, wherein indications of the sub-block structure of a source block are largely determined from headers of physical layer blocks.

14. The electronic delivery system of claim 12, wherein indications of the sub-block structure of a source block can be largely determined from headers of physical layer packets carried in physical layer blocks.

15. The electronic delivery system of claim 12, wherein the sent symbols of data include FEC repair data generated from different sub-blocks and combinations of sub-blocks.

16. The electronic delivery system of claim 12, wherein the sub-blocks of priorities are used to determine a sending order of the sub-blocks.

17. The electronic delivery system of claim 12, wherein the sub-blocks of priorities are used to map the sub-blocks into the physical layer blocks.

18. The electronic delivery system of claim 17, wherein the sub-blocks of priorities mapped into the physical layer blocks are split between different physical layer blocks.

19. A method for transmitting data from a sender to a receiver in an electronic delivery system for delivering data streams over a broadcast channel, wherein the broadcast channel is a channel for conveying signals from one or more sources to a plurality of receivers, wherein each receiver attempts to receive substantially the same signal, the method comprising:
sending data for the data stream within physical layer packets of physical layer blocks from the sender, wherein indications of how the sent data is related to the data stream are based at least in part on the physical layer of blocks.

20. A computer-readable medium comprising computer-executable code for executing the method of claim 19.
